(19) United States
(12) Patent Application Publication
(10) Pub. No.: US 2005/0121065 A1
(43) Pub. Date: Jun. 9, 2005

(54) Thermoelectric module with directly bonded heat exchanger

(76) Inventor: Robert W. Otey, Litchfield, NH (US)

Correspondence Address: MESMER & DELEAULT, PLLC, 41 BROOK STREET, MANCHESTER, NH, 03104, US

(21) Appl. No.: 10/731,053

(22) Filed: Dec. 9, 2003

(51) Int. Cl. H01L 35/30; H01L 35/28

(52) U.S. Cl. 136/205; 136/212

(57) ABSTRACT

A thermoelectric device with an improved thermal efficiency has an object to be heated or cooled having a surface, at least one electrically conductive lower pad bonded directly to the surface of the object using a thermally conductive dielectric material, at least one thermoelectric element coupled on one end to the electrically conductive pad, at least one electrically conductive upper pad coupled to an opposite end of the thermoelectric element, and electrical power connections coupled to the device.

### BACKGROUND OF THE INVENTION

1. Field of the Invention

The present invention relates generally to heat transfer devices and methods of connecting such devices to objects to be heated or cooled. Particularly, the present invention relates to thermoelectric heat transfer devices. More particularly, the present invention relates to thermoelectric devices and a method of fabricating the same.

2. Description of the Prior Art

Thermoelectric cooling was first discovered by Jean-Charles-Athanase Peltier in 1834, when he observed that a current flowing through a junction between two dissimilar conductors induced heating or cooling at the junction, depending on the direction of current flow. This is called the Peltier effect. Practical use of thermoelectrics did not occur until the early 1960s with the development of semiconductor thermocouple materials, which were found to produce the strongest thermoelectric effect. Most thermoelectric materials today comprise a crystalline alloy of bismuth, tellurium, selenium, and antimony.

Thermoelectric devices are solid-state devices that serve as heat pumps. They follow the laws of thermodynamics in the same manner as mechanical heat pumps, refrigerators, or any other apparatus that is used to transfer heat energy. The principal difference is that thermoelectric devices function with solid-state electrical components as compared to more traditional mechanical/fluid heating and cooling components.

Thermoelectric modules are typically used by placing them between a heat source and a heat sink, such as a liquid plate, a surface plate, or a convection heat sink. The thermoelectric module will absorb heat on its “cold” side from the heat source and transfer the heat to its “hot” side and to the heat sink. The heat transfer is typically accomplished by mechanically securing the “hot” and “cold” sides of the thermoelectric module to the heat source and heat sink.

One type of circuit for a simple thermoelectric device generally includes two dissimilar materials such as N-type and P-type thermoelectric semiconductor elements. The thermoelectric elements are typically arranged in an alternating N-type element and P-type element configuration. Most modules have an equal number of P-type and N-type elements and one element of each type shares an electrical interconnection. The elements and the interconnection forms a “couple.” In many thermoelectric devices, semiconductor materials with dissimilar characteristics are connected electrically in series and thermally in parallel. The Peltier effect occurs when voltage is applied to the N-type elements and the P-type elements resulting in current flow through the serial electrical connection and heat transfer across the N-type and P-type elements in the parallel thermal connection.

In another type of circuit, a simple thermoelectric module includes only one type of thermoelectric element, i.e. a P-type or an N-type element, and is known as a single polarity circuit. In this particular circuit, the circuit contains at least one thermoelectric element. Where a plurality of the same type of thermoelectric elements is used, the thermoelectric elements are electrically connected in parallel and the direction of current flow will determine which side of the thermoelectric elements is cooling and which is heating.

In still another type of circuit, a simple thermoelectric module may include several groupings of P-type thermoelectric elements where each group has a plurality of the P-type of thermoelectric elements electrically connected in parallel and several groupings of N-type thermoelectric element where each group has a plurality of the N-type thermoelectric elements electrically connected in parallel. The P-type groupings are electrically connected in series with the N-type groupings.

Typical construction of a thermoelectric module of any circuit type consists of electrically connecting a matrix of thermoelectric elements (dice) between a pair of electrically insulating substrates. The operation of the device creates both a hot-side substrate and a cool-side substrate. The module is typically placed between a load and a sink such as liquid plates, surface plates, or convection heat sinks. The most common type of thermoelectric element is composed of a bismuth-tellurium (Bi₂Te₃) alloy. The most common type of substrate is alumina (96%). A description of conventional thermoelectric modules and technology is also provided in the CRC Handbook of Thermoelectrics and Thermoelectric Refrigeration by H. J. Goldsmid.

A typical thermoelectric device requires DC power in order to produce a net current flow through the thermoelectric elements in one direction. The direction of the current flow determines the direction of heat transfer across the thermoelectric elements. The direction of net, non-zero current flow through the thermoelectric elements determines the function of the thermoelectric device as either a cooler or heater. Examples of these prior art devices are described.

U.S. Pat. No. 6,410,971 (2002, Otey) discloses a flexible thermoelectric module having a pair of flexible substrates, a plurality of electrically conductive contacts on one side of each of the flexible substrates, and a plurality of P-type and N-type thermoelectric elements electrically connected between opposing sides of the pair of flexible substrates having the plurality of conductive contacts where the plurality of conductive contacts connects adjacent P-type and N-type elements to each other in series and where each of the P-type and N-type elements has a first end connected to one of the plurality of conductive contacts of one of the substrates and a second end connected to one of the plurality of electrical contacts of the other of the substrates.

U.S. Pat. No. 6,385,976 (2002, Yamamura et al.) discloses a thermoelectric module where the electrical junctions of either or both sides of the modules are placed in direct thermal contact with a heat source or sink or a material to be thermally modified.

U.S. Pat. No. 6,222,243 (2001, Kishi et al.) discloses a thermoelectric device comprising a pair of substrates each having a surface, P-type and N-type thermoelectric material chips interposed between the pair of substrates, electrodes disposed on the surface of each substrate and connecting adjacent P-type and N-type thermoelectric material chips to each other, and support elements disposed over the surface of each of the substrates for supporting and aligning the thermoelectric material chips on the respective electrodes between the pair of substrates. Each of the thermoelectric material chips has a first distal end connected to one of the electrodes of one of the substrates and a second distal end connected to one of the electrodes of the other of the substrates. The adjacent P-type and N-type thermoelectric material chips connected by the electrodes are interposed between the pair of substrates such that a line connecting centers of the adjacent P-type and N-type thermoelectric material chips is coincident with a diagonal of each of the adjacent P-type and N-type thermoelectric material chips. The substrate used in the Kishi et al. device is a silicon wafer. A disadvantage of using silicon wafers as a substrate is the brittleness of the wafer and the thermal stresses that occur at the junction of the substrate and the thermoelectric material chips.

U.S. Pat. No. 5,362,983 (1994, Yamamura et al.) discloses a thermoelectric conversion module with series connection. The thermoelectric conversion module is constituted by either rows of thermoelectric semiconductor chips or columns of thermoelectric semiconductor chips of the same type. This arrangement improves assembling workability as well as preventing erroneous arrangement. The substrate used in the Yamamura et al. device is a ceramic substrate. A disadvantage of using a ceramic substrate is the stiffness of the ceramic and the thermal stresses that occur at the junction of the substrate and the thermoelectric semiconductor chips when thermally cycled.

While such devices work well, the efficiency is limited by the conventional construction. The most common type of material used to fabricate substrates is 96% alumina. This material has relatively poor thermal conductivity for example approximately 35 watts/m ° C. Since heat, which is transferred from the heat source to the heat sink, must pass through two substrates, both of which have poor conductivity, the efficiency of the device is reduced.

The main disadvantage in conventional thermoelectric use including the use of alumina substrates, polyimide substrates or any other substrates is the limited heat transfer from the heat source to the heat sink since the heat must pass through interface layers from heat source to the thermoelectric element and from the thermoelectric element to the heat sink. Other disadvantages of current thermoelectric module technology require that the substrates be thick enough to withstand cracking. The thicker the module, the heavier the thermoelectric module becomes. Also, material costs for the thicker substrates are higher.

Therefore, what is needed is a thermoelectric module that has an improved thermal efficiency.

### SUMMARY OF THE INVENTION

It is an object of the present invention to provide a thermoelectric module that has an improved thermal efficiency.

The present invention achieves these and other objectives by providing electrical junctions of either or both sides of a thermoelectric module directly bonded to a heat source or sink or an object to be thermally modified (that is, heated or cooled), thus reducing the thermal resistance of the conventional substrate and eliminating the associated thermal interface resistance. An electrically conductive material such as copper, aluminum or any other known electrical conductor exhibiting relatively high thermal conductivity can be used as the electrical junction between a pair of thermoelectric elements.

In one embodiment, the conductive junction is directly bonded to the heat exchanger or heat sink using adhesives or other material capable of adhering the conductive junction to the surface of the heat sink. The adhesives or other material must be a thermally conductive dielectric. The purpose of directly bonding the conductive junctions is to construct a thermoelectric module directly on the object that is being heated or cooled with a substrate on the opposite side of the module or to construct a module between two objects. An advantage of this construction will cause an improvement in the thermal performance of a module by reducing the thermal interface losses in a thermoelectric assembly.

The use of the present inventive module eliminates the need for separate structural substrates, therefore reducing the size of the thermoelectric module as well as increasing efficiency by eliminating interfaces between devices. The reduced size and increased efficiency provided by the present invention can be effectively used in applications such as automotive exhaust pipes and radiators where the thermoelectric device is built into the apparatus. Many other uses could be considered including steam pipes, process piping, ventilation systems, electronics cooling, miniature air coolers, etc.

### BRIEF DESCRIPTION OF THE DRAWINGS

FIG. 1 is a perspective view of one embodiment of the present invention showing an object with the thermoelectric elements directly bonded to the object to be heated or cooled on one side of the thermoelectric module and a substrate on the other side.

FIG. 2 is a perspective view of the embodiment shown in FIG. 1 with the substrate removed.

FIG. 3 is a side view of the embodiment shown in FIG. 1 with the substrate and the upper electrically conductive pads removed.

FIG. 4 is a front view of the embodiment shown in FIG. 3 with the substrate and the upper electrically conductive pads removed.

FIG. 5 is a perspective view of another embodiment of the present invention showing an object with the thermoelectric elements directly bonded to the object to be heated or cooled on one side of the thermoelectric module and a substrate on the other side.

FIG. 6 is a perspective view of the embodiment shown in FIG. 5 with the substrate removed.

FIG. 7 is a side view of the embodiment shown in FIG. 5 with the substrate and the upper electrically conductive pads removed.

FIG. 8 is a front view of the embodiment shown in FIG. 7 with the substrate and the upper electrically conductive pads removed.

### DETAILED DESCRIPTION OF THE PREFERRED EMBODIMENT

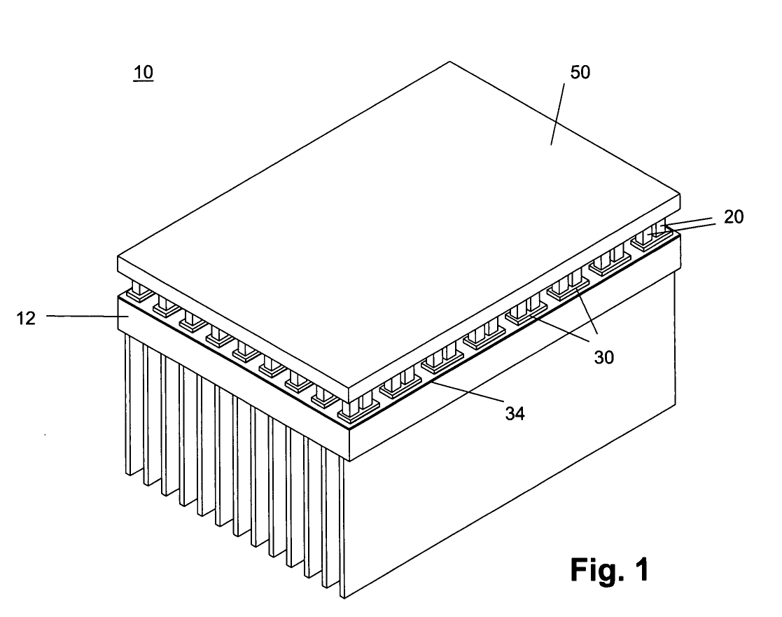

The preferred embodiment of the present invention is illustrated in FIGS. 1-8. FIG. 1 shows a thermoelectric module 10 of the present invention. Module 10 includes an object to be heated or cooled 12, a plurality of thermoelectric elements 20, a plurality of electrically conductive lower pads 30, a plurality of electrically conductive upper pads 40 (not shown), and a reinforcing substrate 50. Each of the plurality of electrically conductive lower pads 30 is directly bonded to a surface 14 of object 12 with a thermally conductive bonding material 34 that is covering at least the surface area of object 12 beneath the plurality of lower pads 30 defined by the perimeter pads of module 10. It is important to note that the thermoelectric module 10 of the present invention does not have a substrate between the object to be heated or cooled 12 and the electrically conductive pads 30 that would provide structural reinforcement to thermoelectric module 10 as provided in the prior art. It is object 12 that provides the required structural reinforcement to thermoelectric module 10. It should be understood that when the term “direct bonding” is used herein, it means that the conductive pads are directly bonded to an object to be heated or cooled using a thermally conductive dielectric material.

It should be understood by those skilled in the art that reinforcing substrate 50 may also be an object to be heated or cooled, i.e. a heat load. It is further noted that the present invention may also incorporate objects to be heated or cooled on both sides of thermoelectric module 10, that thermoelectric module 10 may be a single polarity module containing a single thermoelectric element such as a P-type or an N-type thermoelectric element or a plurality of the same thermoelectric elements connected in parallel, or that it may also incorporate groupings of P-type thermoelectric elements where each group has a plurality of the P-type thermoelectric elements electrically connected in parallel and several groupings of N-type thermoelectric elements where each group has a plurality of the N-type thermoelectric elements electrically connected in parallel. The P-type groupings are electrically connected in series with the N-type groupings.

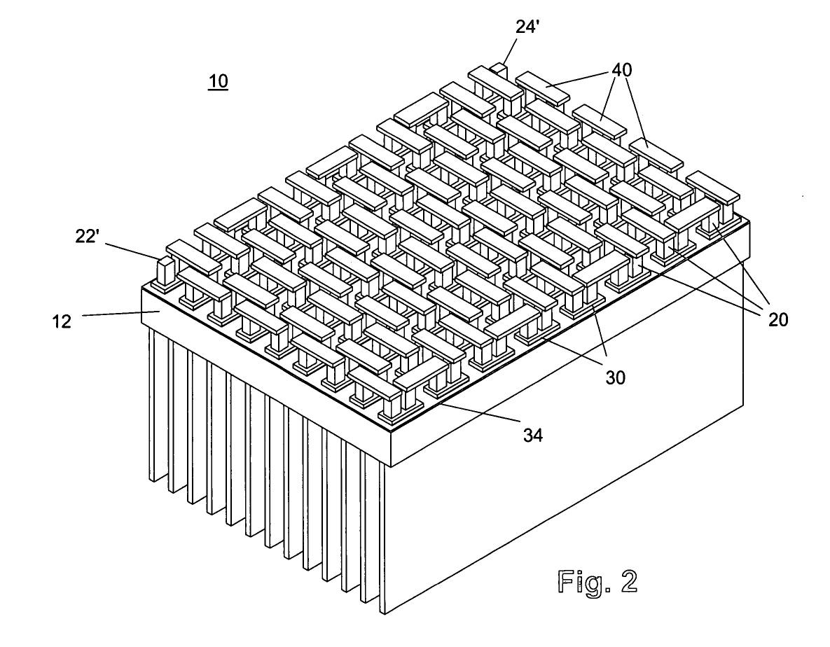

Turning now to FIG. 2, there is illustrated thermoelectric module 10 with the substrate 50 removed. This assembly is the basic functional unit in order to have a working thermoelectric module 10, provided that electrical power is supplied to module 10. The basic thermoelectric module 10 includes an object 12 to be heated or cooled, a plurality of thermoelectric elements 20, a plurality of lower pads 30 where each pad is bonded to surface 14 with bonding material 34, and a plurality of electrically conductive upper pads 40. Thermoelectric elements 20 are electrically coupled to lower pads 30 and upper pads 40 and, in this embodiment, include a plurality of P-type and N-type thermoelectric elements 22 and 24, respectively. The electrical connections couple the thermoelectric elements 20 into an array in a manner similar to that of conventional thermoelectric modules. In a single polarity module, a single thermoelectric element, for example, may be used to cool an electronic chip.

The lower pads 30 and upper pads 40 are fabricated from a material that is both a good electrical and a good thermal conductor such as copper, aluminum, or other material. Heat will be conducted through the pads and bonding material 34 directly to object 12 without passing through a reinforcing substrate. The substrates present in the prior art thermoelectric modules are eliminated, resulting in increased heat transfer and thermal efficiency.

Each conductive pad 30 is electrically coupled through thermoelectric elements 22 and 24 to the remaining plurality of conductive pads 30 in series in alternating fashion. In other words in an embodiment with alternating P-type and N-type elements, a P-type element 22 is electrically connected to an N-type element 24 on another electrically conductive pad. The series chain of thermoelectric elements is connected to an electrical power source so that current flows in order to power the thermoelectric module 10 in a conventional manner. For example, an outside electrical power source is coupled to a P-type element 22′ and an N-type element 24′, one at the beginning of the electrically coupled series of thermoelectric elements 20 and the other at the end of the electrically coupled series of thermoelectric elements 20. In the illustration, the electrical power source connections are made to the same side of thermoelectric module 10 and thus use an equal number of P-type and N-type elements. It should be noted that the electrical power source connections may be made on opposite sides of thermoelectric module 10 and thus would use an unequal number of P-type and N-type elements.

In addition, it is important to note that reinforcing substrate 50 is not required. Upper pads 40 may be direct bonded with a thermally conductive dielectric material to another object (not shown) to be heated or cooled. Those skilled in the art will recognize that this system may as easily be used as an electrical generator by direct bonding objects on either side of thermoelectric module 10 that are at distinctly different temperatures. Such distinctly different temperatures will produce a thermal gradient on thermoelectric module 10 resulting in the development of a DC electrical current in a direction dependent on which of the objects is hotter or cooler.

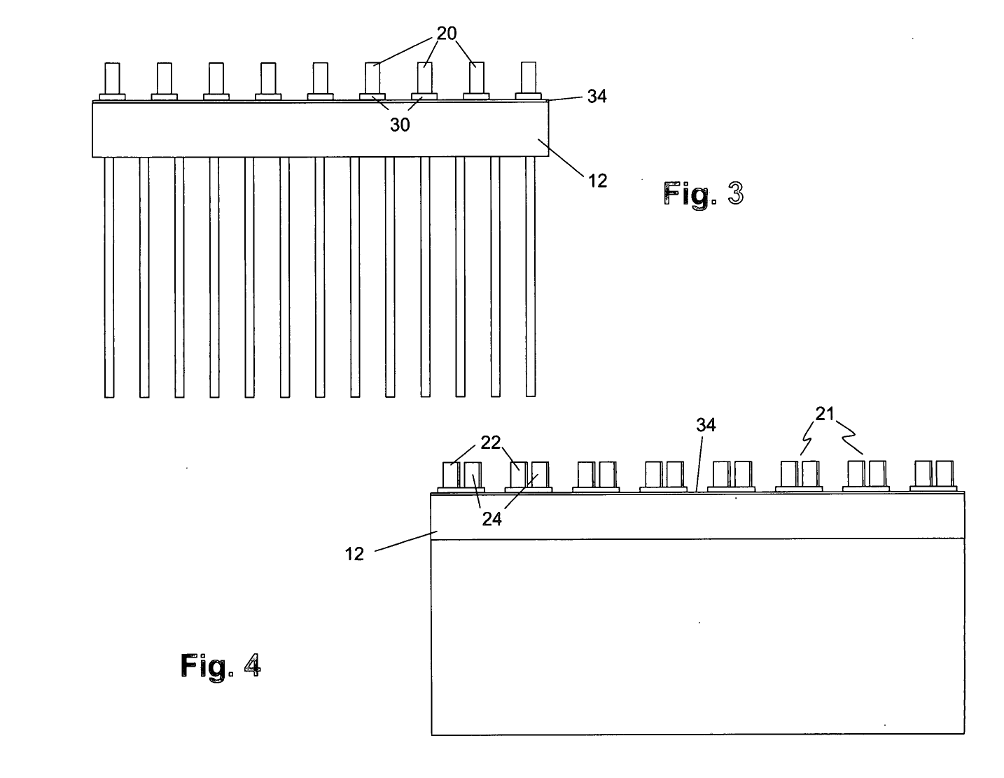

FIG. 3 is a side view of a partially assembled thermoelectric module 10. The plurality of lower pads 30 are bonded to object 12 to be heated or cooled using thermally conductive dielectric bonding material 34. Bonding material 34 may be a thermally conductive dielectric adhesive or a polymer bonding composition or a thermoplastic material capable of coupling the lower pads 30 to the surface 14 (not shown) of object 12, or any other thermally conducting dielectric material that is capable of direct bonding to an object being heated or cooled. It is important to note that the thickness and/or composition of bonding material 34 is such that the coating provided under each conductive pad is not necessarily capable of having structural reinforcing properties sufficient to support the array of electrically conductive pads 30 and thermoelectric elements 20 without the use of an object 12 or a reinforcing substrate such as those substances being used in the prior art, for example, those using flexible substrates such as tape or polyimide sheeting. In particular, the thermally conductive dielectric material should have relatively high resistance to thermal cycling fatigue, relatively high dielectric strength, a broad operating temperature range, and relatively good heat transfer characteristics. The preferred material used in the present invention is a polyimide material. A general criteria for selecting a given thermally conductive dielectric material is the material's tensile strength, its thermal conductivity, i.e. its ability to transfer heat, and its ability to withstand thermal stresses associated with thermal cycling of thermoelectric devices. FIG. 4 is a front view of FIG. 3 showing the thermoelectric element pairs 21 on each lower pad 30, which are bonded to surface 14 of object 12 with bonding material 34.

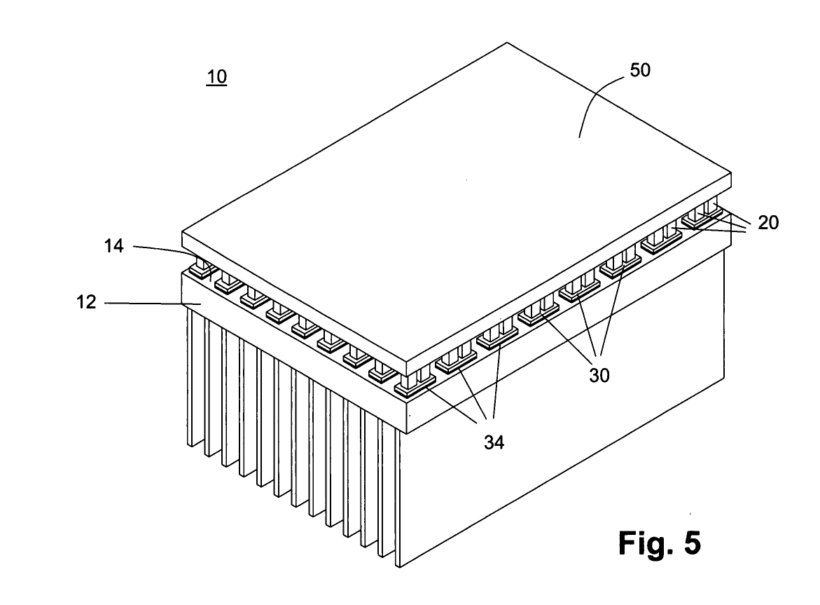

Turning now to FIG. 5, there is illustrated another embodiment of thermoelectric module 10. In this embodiment, thermoelectric module 10 includes an object to be heated or cooled 12, a plurality of thermoelectric elements 20, a plurality of electrically conductive lower pads 30, a plurality of electrically conductive upper pads 40 (not shown), and a reinforcing substrate 50. Each of the plurality of electrically conductive lower pads 30 is directly bonded to a surface 14 of object 12 with a thermally conductive bonding material 34 that is covering only the surface area of object 12 beneath each of the lower pads 30. Like the embodiment in FIG. 1, thermoelectric module 10 of this embodiment does not have a reinforcing substrate between the object to be heated or cooled 12 and the electrically conductive pads 30 that would provide structural reinforcement to thermoelectric module 10 as provided in the prior art. It is object 12 that provides the required structural reinforcement to thermoelectric module 10. The difference between the embodiments in FIGS. 1 and 5 is that the entire surface 14 of object 12 upon which the array or plurality of lower pads 30 are bonded is coated with thermally conductive dielectric bonding material 34 instead of bonding material 34 being limited to beneath only the lower pads 30 themselves.

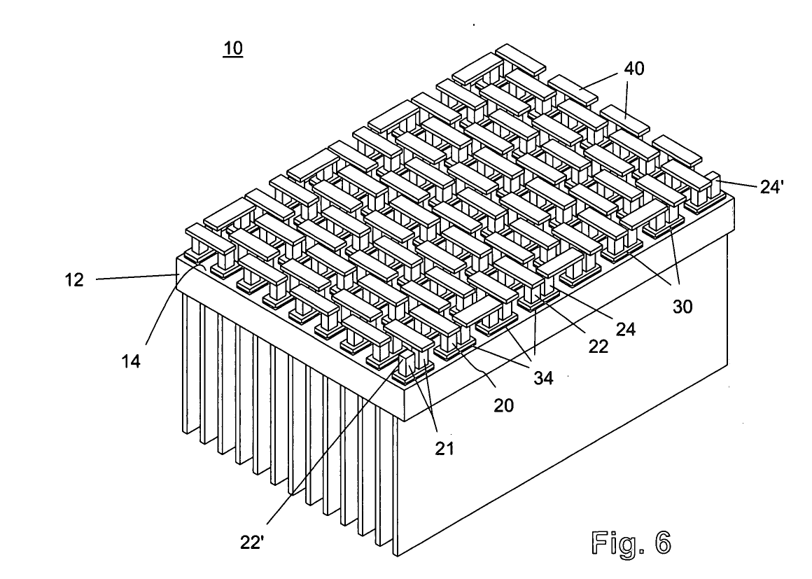

Like FIG. 2, FIG. 6 illustrates a basic thermoelectric module 10 of the second embodiment with the reinforcing substrate 50 removed. The basic thermoelectric module 10 of this embodiment includes an object 12 to be heated or cooled, a plurality of thermoelectric elements 20, a plurality of lower pads 30 bonded to surface 14 (not shown) with bonding material 34, and a plurality of electrically conductive upper pads 40. Thermoelectric elements 20 are electrically coupled to lower pads 30 and upper pads 40 and include an equal number of P-type and N-type thermoelectric elements 22 and 24, respectively. As previously disclosed, whether the power connections to the module are made on the same side or on opposite sides will determine whether the number of thermoelectric elements used in the module is even or odd.

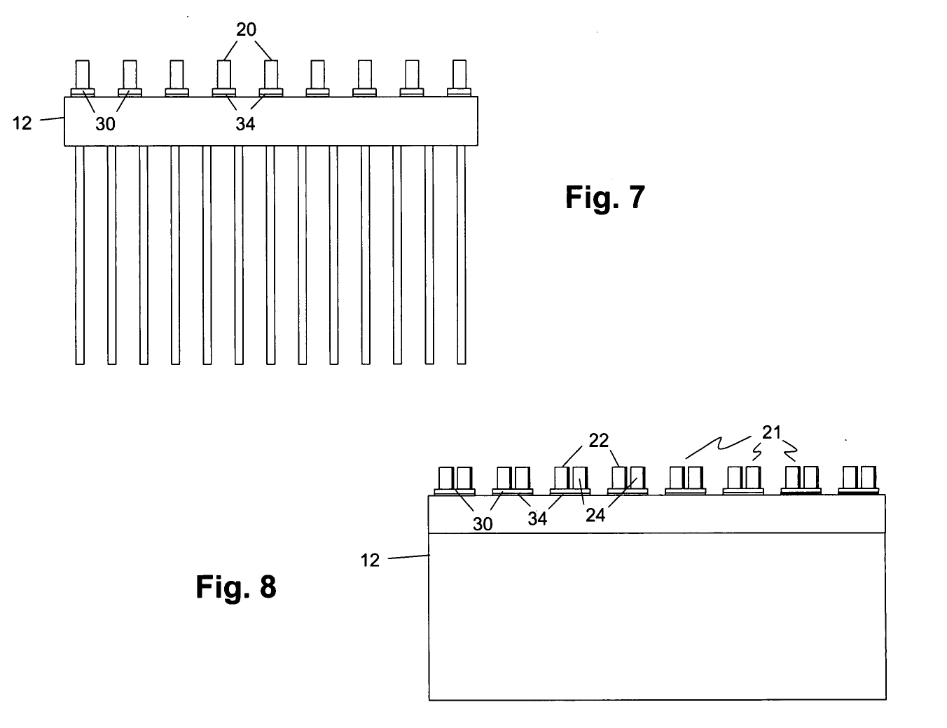

FIG. 7 is a side view of a partially assembled thermoelectric module 10 of the embodiment shown in FIG. 6. The plurality of lower pads 30 are bonded to object 12, which is to be heated or cooled, using thermally conductive dielectric bonding material 34. Bonding material 34 may be a thermally conductive dielectric adhesive or a polymer bonding composition or a thermoplastic material capable of coupling the lower pads 30 to the surface 14 of object 12. FIG. 8 is a front view of FIG. 7 showing the thermoelectric element pairs 21 on each lower pad 30, which are bonded to surface 14 of object 12 with bonding material 34.

Although various methods and processes may be used to accomplish the direct bonding of the thermoelectric module's conductive pads to the object or objects to be heated or cooled including, but not limited to, the use of adhesives, epoxies, ect., the preferred method of bonding the conductive pads to an object 12 is as follows. A portion of a polyimide sheet coated with, laminated with, or otherwise bonded with a layer of an electrically conductive material, preferably copper, on one side is used to form electrically conductive pad 30. Such polyimide sheeting with a conductive coating such as copper is available under the tradename/trademark DuPont TC available from E. I. du Pont de Nemours and Company, Flexible Circuit Division, Raleigh, N.C. The conductive pad circuit pattern for the thermoelectric module is etched into the conductive coating of the polyimide sheet. The sheet is then placed against the surface of the object to be heated or cooled. The object surface and sheet then undergo a high pressure and high temperature process to reflow the polyimide. The reflowed polyimide resets upon cooling and bonds the conductive pad circuit to the object. The polyimide becomes the thermally conductive bonding material that couples the conductive pads to the object's surface. The general parameters of the high pressure and high temperature process are known or are easily obtained by those of ordinary skill in the art and the determination of optimum ranges for a particular direct-bonded thermoelectric module configuration and density can be obtained without any undue experimentation.

Alternatively, the polyimide sheet may be placed against the surface of the object to be heated or cooled, processed through the high pressure and high temperature treatment to bond the conductive layer of the polyimide sheet to the surface of the object, and then etched with the conductive pad pattern circuit. The polyimide sheet may also be cut into individual conductive pads which are then placed against the surface of the object to be heated or cooled and treated with the high pressure and high temperature process.

Once the conductive pad circuit is bonded to the surface of the object to be heated or cooled, the copper of the conductive pad may then be optionally pre-tinned to prepare the surface for soldering the thermoelectric element thereto. Thermocouple semiconductor material (such as, for example, Bi₂Te₃ alloy) appropriate for forming thermoelectric elements is cut to the desired size. The size of the thermoelectric element depends on the heat pump capacity needed for the thermoelectric device 10, which can be easily determined by those skilled in the art.

The ends of each thermoelectric element may optionally be coated with a diffusion barrier, preferably nickel. To reduce the cost of making a thermoelectric device 10, the diffusion barrier step may be eliminated. However, it should be understood that the useful life of the thermoelectric device 10 will be shortened because of copper migration into the thermoelectric elements.

The thermoelectric elements are then attached, preferably by soldering, to the pre-tinned, electrically conductive pads 30 by manually picking and placing the thermoelectric elements on the electrically conductive pads, preferably using an alignment grid or screen, or by using an automated system that performs the placement and alignment and soldering, or by using a semi-automated pick and place system that solders the components.

Those skilled in the art will understand that an alternative assembly technique would be to electrically couple the thermoelectric element to the electrically conductive pad having the polyimide material on the opposite side of the conductive pad and then placing the electrically conductive pad with the coupled thermoelectric element against the surface of the object to be heated or cooled. The polyimide material is then treated to the high pressure and high temperature process to directly bond the conductive pad to the surface of the object.

It should be understood by those of ordinary skill in the art that the direct-bonded module eliminates the customary substrate between the conductive pads and the surface of the object to be heated or cooled and, thus, provides for a more efficient thermoelectric module, a lower module profile, and reduced assembly costs. Further, the elimination of the traditional substrate is also advantageous in assemblies where thermoelectric elements are stacked.

It should be further understood that the direct bonding of the conductive pads to the object to be heated or cooled may be accomplished with other process means and thermally conductive adhesive-type materials to accomplish the same result. The end result is the elimination of the substrate layer (rigid or flexible) between the conductive pads of the thermoelectric module and the surface of the object where no additional coatings (metallized or otherwise) are required to bond the conductive pads to the surface.

With regard to the preferred method of reflowing a polyimide layer under high pressure and high temperature, this process of using a fixed polyimide layer that is not a thermally-activated bonding material such as polyetherimide or a siloxane polyetherimide copolymer (also known as “thermoplastic polyimide”) can also be used to bond heat sinks to other power semiconductor devices. Like the method's use with thermoelectric modules, this process will provide enhanced thermal conductive characteristics for transferring heat from other power semiconductor devices by directly bonding the heat sink to the power semiconductors or other electronic components that require coupling to a heat sink. This direct-bonding method provides better adhesive properties over other prior art methods.

Although the preferred embodiments of the present invention have been described herein, the above description is merely illustrative. Further modification of the invention herein disclosed will occur to those skilled in the respective arts and all such modifications are deemed to be within the scope of the invention as defined by the appended claims.

1. A thermoelectric module comprising:
an object to be heated or cooled having a surface;
at least one electrically conductive lower pad bonded directly to said surface of said object with a thermally conductive dielectric material;
at least one thermoelectric element coupled on one end to said at least one electrically conductive pad; and
at least one electrically conductive upper pad coupled to an opposite end of said at least one thermoelectric element; and
electrical power connections coupled to said module.

2. The module of claim 1 further comprising a substrate disposed on said at least one electrically conductive upper pad.

3. The module of claim 1 further comprising a second object to be heated or cooled having a surface bonded directly to said at least one electrically conductive upper pad.

4. The module of claim 1 wherein said thermally conductive dielectric material is any thermally conductive material capable of bonding said at least one conductive lower pad to said surface.

5. The module of claim 4 wherein said thermally conductive dielectric material is a thermally conductive dielectric adhesive.

6. The module of claim 4 wherein said thermally conductive dielectric material is a thermally conductive dielectric polymer.

7. The module of claim 1 wherein said module is a single polarity thermoelectric module.

8. The module of claim 1 wherein said at least one thermoelectric element is selected from the group consisting of a P-type thermoelectric element and an N-type thermoelectric element.

9. A thermoelectric module comprising:
an object to be heated or cooled, said object having a surface;
an array of electrically conductive lower pads bonded directly to said surface of said object with a thermally conductive dielectric material wherein said object provides the reinforcing structural integrity of a substrate;
at least one thermoelectric element coupled on one end to each of said array of electrically conductive lower pads forming an array of thermoelectric elements;
a plurality of electrically conductive upper pads coupled to an opposite end of said array of thermoelectric elements; and
electrical power connections coupled to said module.

10. The module of claim 9 further comprising a substrate disposed on said plurality of electrically conductive upper pads on said opposite end of said array of thermoelectric elements.

11. The module of claim 9 further comprising a second object having a surface bonded directly to said plurality of electrically conductive upper pads on said opposite end of said array of thermoelectric elements.

12. The module of claim 9 wherein said thermally conductive dielectric material is any thermally conductive dielectric material capable of bonding said array of electrically conductive lower pads to said surface.

13. The module of claim 12 wherein said thermally conductive dielectric material is a thermally conductive dielectric adhesive.

14. The module of claim 12 wherein said thermally conductive dielectric material is a thermally conductive dielectric polymer.

15. A direct bonded thermoelectric module comprising:
an object to be heated or cooled, said object having a surface;
electrically conductive means bonded directly to said surface of said object with a thermally conductive dielectric bonding means wherein said object provides the reinforcing structural integrity of a substrate in place of substrate;
at least one thermoelectric element coupled on one end to said electrically conductive means; and
electrical connection means coupled to an opposite end of said at least one thermoelectric element; and
electrical power means coupled to said module.

16. A method of making a thermoelectric module having an improved thermal efficiency, said method comprising:
direct bonding at least one electrically conductive lower pad to a surface of an object to be heated or cooled with a thermally conductive dielectric material;
electrically coupling at least one thermoelectric element on one end to said at least one electrically conductive lower pad;
electrically coupling at least on electrically conductive upper pad to an opposite end of said at least one thermoelectric element; and
electrically coupling electrical power connections to said module.

17. The method of claim 16 further comprising bonding a thermally conductive substrate to said at least one electrically conductive upper pad.

18. The method of claim 16 further comprising direct bonding a second object to be heated or cooled to said at least one electrically conductive upper pad.

19. A method for direct bonding of a thermoelectric element to an object to be heated or cooled, said method comprising:
forming at least one electrically conductive pad onto one side of a thermally conductive dielectric material;
placing said thermally conductive dielectric material against a surface of an object to be heated or cooled;
treating said thermally conductive dielectric material to cause said thermally conductive dielectric material to directly bond to said surface of said object; and
electrically coupling said thermoelectric element to said at least one electrically conductive pad.
